(19) United States
(12) Patent Application Publication
(10) Pub. No.: US 2025/0385624 A1
(43) Pub. Date: Dec. 18, 2025

(54) POWER CONDITIONING SYSTEM FOR REDUCED-VOLTAGE SOFT STARTERS CONFIGURED TO OPERATE WITH LONG SHIELDED LOAD CABLES

(71) Applicant: Eaton Intelligent Power Limited, Dublin 4 (IE)

(72) Inventors: Stan Rex Simms, Arden, NC (US); Thomas A. Farr, Candler, NC (US)

(21) Appl. No.: 19/233,265

(22) Filed: Jun. 10, 2025

Related U.S. Application Data
(60) Provisional application No. 63/659,551, filed on Jun. 13, 2024.

(51) Int. Cl. H02P 1/26; H02H 7/08; H02J 3/16; H02J 7/00; H02J 7/34; H03K 17/0812

(52) U.S. Cl. CPC H02P 1/26; H02H 7/0811; H02J 3/16; H02J 7/00714; H02J 7/345; H03K 17/0812; H02J 2207/20; H02J 2207/50

(57) ABSTRACT

Some aspects of the present inventive concepts relate to a power conditioning unit for reduced-voltage soft starters (RVSS) in medium voltage motor control centers. The system mitigates issues caused by long shielded cables, such as high rates of current change (di/dt) and parasitic capacitance. The power conditioning unit, which can include a power factor correction capacitor (PFCC), a smoothing inductor, and a series fuse, may remain continuously connected in the circuit in some configurations. This setup can eliminate the need for a power conditioning unit capacitor contactor, thereby simplifying the operational complexity. The PFCC provides reactive power compensation, and has the potential to reduce voltage sag during high-slip start/stop events.

### RELATED APPLICATIONS

The present application claims priority benefit to U.S. Provisional Application No. 63/659,551, entitled “Power Conditioning System for Enhanced Durability in Reduced-Voltage Soft Starters with Long Shielded Cables,” filed Jun. 13, 2024, which is hereby incorporated herein by reference in its entirety.

### FIELD

The present disclosure generally relates to the field of electrical power systems, and, more particularly, to component configurations within reduced voltage soft starters used with long load cables and line power conditioning.

### BACKGROUND

Reduced-voltage soft starters (RVSS) can be used in industrial motor applications to limit inrush current and reduce mechanical stress during startup. These devices are often applied in medium or high voltage systems, where controlling current during ramp-up can help reduce voltage sag on the source side.

In some cases, systems that include long shielded load cables can exhibit parasitic capacitance distributed along the cable length. This parasitic capacitance can result in high rates of current change (di/dt), which can place electrical stress on components within the RVSS. These di/dt conditions can be particularly pronounced during motor start and stop events, especially where line-side power factor correction (PFC) capacitors or surge suppression elements are also present. In many applications, cables longer than several hundred feet or exhibiting parasitic capacitance in the range of a few tenths of a microfarad can give rise to such effects, depending on system configuration and loading.

Silicon Controlled Rectifiers (SCRs) are commonly used in RVSS units to control voltage to the load. However, SCRs can be susceptible to damage when exposed to elevated di/dt conditions caused by charging or discharging cable capacitance. Some approaches have employed series-connected smoothing inductors to manage di/dt effects, but installing such inductors on each RVSS within a medium voltage motor control center (MCC) can introduce design constraints related to space, cost, and thermal considerations.

Different mitigation strategies have been used, including inductor-capacitor arrangements and switching schemes. The effectiveness of these approaches can depend on characteristics of the local power system, the length and configuration of load cables, and operating conditions.

Power conditioning capacitors, such as PFC banks, can be managed with contactors that respond to the RVSS ramp sequence. While long cables alone may not cause SCR failure, combining them with line-side capacitors can result in charging di/dt events that affect RVSS operation. Surge capacitors are sometimes used to attenuate fast voltage transients such as those from lightning, but in RVSS systems, phase-controlled waveforms can produce steep rising edges that, if surge capacitors are present, can lead to additional di/dt stress unless current is smoothed with an inductor.

### SUMMARY

Certain illustrative examples are described in the following numbered clauses:

Clause 1. A system for regulating power delivery to a load, the system comprising:
a reduced-voltage soft starter (RVSS) comprising a plurality of silicon-controlled rectifiers (SCRs), the SCRs positioned to regulate voltage applied to the load;
a contactor electrically coupled between a power source and the RVSS, the contactor configured to selectively establish or interrupt electrical continuity between the power source and the RVSS; and
a power conditioning circuit electrically coupled between the power source and the load in parallel with the RVSS, the power conditioning circuit comprising a power factor correction capacitor, and a smoothing inductor electrically connected in series with the power factor correction capacitor,
wherein the smoothing inductor and the power factor correction capacitor define a conductive path positioned to carry current between the power source and the load independently of the RVSS, and
wherein the conductive path is arranged to attenuate current transients resulting from interaction between the power factor correction capacitor and a parasitic capacitance of a shielded cable electrically coupling the RVSS to the load.

Clause 2. The system of Clause 1, wherein the smoothing inductor is electrically positioned between the power factor correction capacitor and a junction with the shielded cable, and is dimensioned to oppose a rate of current change associated with interaction between the power factor correction capacitor and the parasitic capacitance of the shielded cable.

Clause 3. The system of any of the preceding clauses, wherein the power conditioning circuit is electrically coupled in a shunt path that bypasses the RVSS and provides a continuous conductive route between the power source and the load.

Clause 4. The system of Clause 3, wherein the conductive route formed by the power conditioning circuit remains closed during both energization and de-energization of the RVSS.

Clause 5. The system of any of the preceding clauses, wherein the power factor correction capacitor and the smoothing inductor are arranged to form an LC network with the shielded cable capacitance, such that peak transient currents are diverted from the SCRs.

Clause 6. The system of any of the preceding clauses, further comprising a shielded cable electrically coupled between the RVSS and the load, the shielded cable having the parasitic capacitance.

Clause 7. The system of Clause 6, wherein the parasitic capacitance of the shielded cable is at least 0.3 microfarads.

Clause 8. The system of Clause 6, wherein the shielded cable has a length greater than 800 feet.

Clause 9. The system of any of the preceding clauses, wherein the smoothing inductor comprises a magnetic core selected from the group consisting of iron-core, ferrite-core, laminated steel-core, powder iron-core, or nanocrystalline-core.

Clause 10. The system of any of the preceding clauses, wherein the power conditioning circuit further comprises a fuse electrically connected in series with the power factor correction capacitor and the smoothing inductor.

Clause 11. The system of any of the preceding clauses, wherein the power factor correction capacitor is electrically positioned on a side of the contactor that is electrically proximate to the power source.

Clause 12. The system of any of the preceding clauses, wherein the power factor correction capacitor is electrically positioned on a side of the contactor that is electrically proximate to the load.

Clause 13. The system of any of the preceding clauses, wherein the power conditioning circuit is electrically connected without a contactor or switch for disconnecting the power factor correction capacitor.

Clause 14. The system of any of the preceding clauses, wherein the RVSS omits a bypass contactor connected in parallel with the SCRs.

Clause 15. The system of any of the preceding clauses, wherein the smoothing inductor is electrically connected between a terminal of the power factor correction capacitor and a conductive node shared with the shielded cable, the power factor correction capacitor and the smoothing inductor being electrically connected in series with a fuse to form a continuous, unbroken conduction path from the power source to the load, the conduction path bypassing the SCRs, wherein the smoothing inductor has an inductance value selected such that peak di/dt resulting from a transient charging or discharging event between the power factor correction capacitor and a parasitic capacitance of the shielded cable remains below a rate of current change capable of triggering or damaging the SCRs.

Clause 16. The system of any of the preceding clauses, wherein the conductive path defined by the smoothing inductor and the power factor correction capacitor is electrically connected during a startup sequence of the reduced-voltage soft starter, and wherein the conductive path limits a peak current surge associated with energization of the parasitic capacitance of the shielded cable.

Clause 17. The system of any of the preceding clauses, wherein the power conditioning unit further comprises a series fuse electrically connected in series with the PFCC.

Clause 18. The system of any of the preceding clauses, wherein the power conditioning unit assists in ramp start/stop operations of the RVSS by providing leading reactive power (VARs) during high-slip start/stop events, thereby reducing voltage sag at a point of common coupling (PCC) and mitigating current surges through the SCRs.

Clause 19. The system of any of the preceding clauses, wherein the RVSS comprises:
a starter electrically coupled to a medium voltage power source, the starter comprising the main contactor, the main contactor configured to connect the RVSS to the medium voltage power source, the main contactor closing to allow current flow through the circuit; and
the SCRs electrically coupled between the main contactor and a load.

Clause 20. The system of any of the preceding clauses, wherein the PFCC is energized concurrently with a closing of the main contactor, providing immediate reactive power support and reducing a voltage sag during an RVSS ramp start.

Clause 21. The system of any of the preceding clauses, wherein the power conditioning unit further comprises a vacuum contactor connected in series with the PFCC, configured to connect and disconnect the PFCC.

Clause 22. The system of any of the preceding clauses, wherein the power conditioning unit does not include a vacuum contactor.

Clause 23. The system of any of the preceding clauses, wherein the smoothing inductor is one of an air-core inductor, an iron-core inductor, a ferrite-core inductor, a laminated steel-core inductor, a powder iron-core inductor, or a nanocrystalline-core inductor.

Clause 24. The system of any of the preceding clauses, wherein the smoothing inductor is configured to limit the di/dt through the SCRs, the inductor being positioned in a shunt path to smooth current from line-side PFCC to load-side parasitic capacitance.

Clause 25. The system of any of the preceding clauses, wherein the PFCC is one of a two-, three- or four-terminal device, and is operable in one of a three-phase configuration or a single-phase configuration.

Clause 26. The system of any of the preceding clauses, wherein the power conditioning unit is coupled to the load side of the main contactor.

Clause 27. The system of Clause 26, wherein the power conditioning unit does not include a vacuum contactor.

Clause 28. The system of any of the preceding clauses, wherein the power conditioning unit is coupled to the line side of the main contactor.

Clause 29. The system of any of the preceding clauses, wherein the circuit comprises a long shielded cable, the long shielded cable introducing parasitic capacitance into the system, a total length of the long shielded cable exceeding 800 ft.

Clause 30. The system of any of the preceding clauses, wherein the circuit comprises a long shielded cable, the long shielded cable introducing a load-side parasitic capacitance into the system of at least 0.3 uF.

Clause 31. The system of any of the preceding clauses, wherein the PFCC is configurable to be activated independently from the main contactor or independently from a bypass contactor, enabling modulation of its operation based on detected electrical conditions in the circuit.

Clause 32. The system of any of the preceding clauses, wherein the power conditioning unit mitigates effects of inherent parasitic capacitance in shielded cables used in the circuit, thereby inhibiting high di/dt currents through the device.

Clause 33. The system of any of the preceding clauses, wherein the power conditioning unit facilitates a reduction in a magnitude and/or a duration of voltage sag encountered during an activation of the RVSS.

Clause 34. The system of any of the preceding clauses, wherein the RVSS does not include a smoothing inductor positioned in series with the SCRs.

Clause 35. The system of any of the preceding clauses, wherein the RVSS does not include a bypass contactor for bypassing the RVSS following motor ramp-up.

Clause 36. The system of any of the preceding clauses, wherein the RVSS is configured to operate without an external reactive power compensation device separate from the PFCC included in the power conditioning unit.

Clause 37. The system of any of the preceding clauses, wherein the RVSS does not require a separate control circuit for managing the switching of the bypass contactor and/or reactor contactor.

Clause 38. The system of any of the preceding clauses, wherein the power conditioning unit does not utilize any external capacitors other than the PFCC included within the power conditioning unit.

Clause 39. The system of any of the preceding clauses, wherein the RVSS operates without the need for additional external inductors to manage parasitic capacitance.

Clause 40. The system of any of the preceding clauses, wherein the RVSS does not include an external snubber circuit across the SCRs.

Clause 41. The system of any of the preceding clauses, wherein the system allows for a surge capacitor to be fitted on the load without changing di/dt effects or RVSS ramp start/stop.

Clause 42. A method of regulating power delivery to a load, the method comprising: energizing a reduced-voltage soft starter (RVSS) from a power source, the RVSS comprising a plurality of silicon-controlled rectifiers (SCRs) electrically coupled to a contactor;
closing the contactor to apply voltage from the power source through the RVSS to the load via a shielded cable;
operating the SCRs to regulate voltage to the load during a startup or shutdown sequence;
conducting current from the power source to the load through a power conditioning circuit electrically connected in parallel with the RVSS, the power conditioning circuit comprising a power factor correction capacitor and a smoothing inductor connected in series; and
passing current through the smoothing inductor in the power conditioning circuit to attenuate transient current caused by interaction between the power factor correction capacitor and a parasitic capacitance of the shielded cable,
wherein the current conducted through the power conditioning circuit bypasses the SCRs of the RVSS.

Clause 43. The method of Clause 42, wherein conducting current through the power conditioning circuit comprises establishing an uninterrupted electrical conduction path from the power source to the load through the smoothing inductor and the power factor correction capacitor, the conduction path bypassing the contactor and the SCRs of the reduced-voltage soft starter throughout a startup sequence.

Clause 44. The method of Clause 42, wherein the current conducted through the power conditioning circuit includes a reactive charging current arising from interaction between the power factor correction capacitor and a parasitic capacitance of the shielded cable, and wherein the reactive charging current is directed through the smoothing inductor and excluded from the conduction path of the SCRs.

Clause 45. The method of Clause 42, wherein passing current through the smoothing inductor includes limiting a rate of change of current associated with an initial energization of the parasitic capacitance of the shielded cable to a value less than a predetermined maximum di/dt threshold of the silicon-controlled rectifiers.

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1 illustrates a prior art circuit for a medium voltage motor control center including a reduced-voltage soft starter (RVSS) connected to a motor via a long shielded cable.

FIGS. 2A and 2B illustrate block diagrams of example RVSS systems that include a power conditioning unit.

FIG. 2C illustrates an example block diagram of a system including multiple RVSS units, each connected to a respective load through a long shielded cable and configured to share a common power conditioning unit.

### DETAILED DESCRIPTION

### Introduction

Electrical power systems used in industrial, commercial, or utility environments can involve the controlled delivery of electrical energy to various types of loads. In many situations, it may be helpful to manage voltage transitions during startup or shutdown to reduce electrical disturbances, limit current surges, or improve overall system behavior. Reduced-voltage soft starters (RVSS) are often used in such contexts, for example, in medium or high voltage systems, to gradually ramp voltage using phase-angle control through silicon-controlled rectifiers (SCRs).

In some installations, RVSS systems are coupled to loads via long shielded cables. These cables can introduce distributed parasitic capacitance that may interact with the waveforms produced by SCR-based phase control. This interaction might contribute to high rates of current change (di/dt), which could impose electrical stress on SCRs or other system components. In some cases, additional reactive components such as power factor correction (PFC) capacitors or surge capacitors might further influence these conditions, potentially affecting the consistency of soft-start or soft-stop behavior.

Some inventive concepts described herein relate to RVSS configurations that may help reduce or manage electrical effects associated with long shielded cables or reactive circuit elements. In some examples, a smoothing inductor is positioned in a conductive shunt path that includes a power factor correction capacitor. This path may bypass the RVSS and allow current to flow between the source and the load in a way that moderates di/dt effects linked to parasitic capacitance. In some implementations, this conduction path may remain continuously connected during both startup and shutdown sequences, providing a persistent bypass for current independent of SCR conduction. In some scenarios, energizing the PFC capacitor in coordination with the main contactor might help reduce reactive current drawn during startup. This may include current used to initially charge the parasitic capacitance of the shielded cable, which is diverted through the smoothing inductor and away from the SCRs.

These and other arrangements may also be useful during shutdown sequences. As voltage applied to the load is reduced, discharge behavior of parasitic capacitance or other reactive components could give rise to transient currents. A smoothing inductor, when positioned between line-side and/or load-side capacitance, may limit the rate of change in current during this process and help reduce associated electrical stress. In some examples, the inductance value may be selected to ensure that peak di/dt remains below a maximum threshold tolerated by the SCRs. Adjusting the timing or duration of PFC capacitor engagement during ramp-down may further support voltage stability.

Some inventive concepts described herein can be implemented in various RVSS architectures, including single-unit or multi-unit systems. The approach may be adapted for different load types, cable configurations, or installation constraints. In some situations, these techniques may contribute to improved electrical performance or operational consistency in systems that include RVSS devices, power conditioning features, or capacitive loading.

RVSS devices are often used in industrial motor applications to help reduce inrush current or mechanical stress during startup. These systems typically include SCRs that regulate voltage in a controlled ramp-up. However, in scenarios involving long shielded cables, the associated parasitic capacitance may give rise to elevated di/dt conditions, which in turn may increase the risk of SCR damage. In some cases, this could necessitate bypassing the RVSS and using full-voltage starting, thereby negating the benefits of soft start. By maintaining a parallel power conditioning circuit that diverts reactive charging current away from the RVSS, some inventive concepts described herein may help preserve RVSS functionality in such environments.

Some inventive concepts described herein involve incorporating a smoothing inductor in a series arrangement with a power factor correction capacitor to form a continuous shunt path around the RVSS. This path may remain energized even when the RVSS is not conducting, which can support consistent attenuation of current transients. In some examples, this configuration may reduce the need for placing individual inductors adjacent to each RVSS unit, thereby simplifying installation or reducing system complexity. The continuous nature of this conduction path may also provide passive mitigation of parasitic capacitance effects regardless of RVSS switching state.

Some inventive concepts described herein offer a practical approach to managing electrical transients in systems that employ RVSS devices in combination with long shielded cables or capacitive components. Benefits may include, but are not limited to, improved tolerance to installation variability, enhanced protection of switching components, or better voltage control during transitional states. In some cases, such configurations could help support more flexible system deployment across a range of environments.

### System Overview

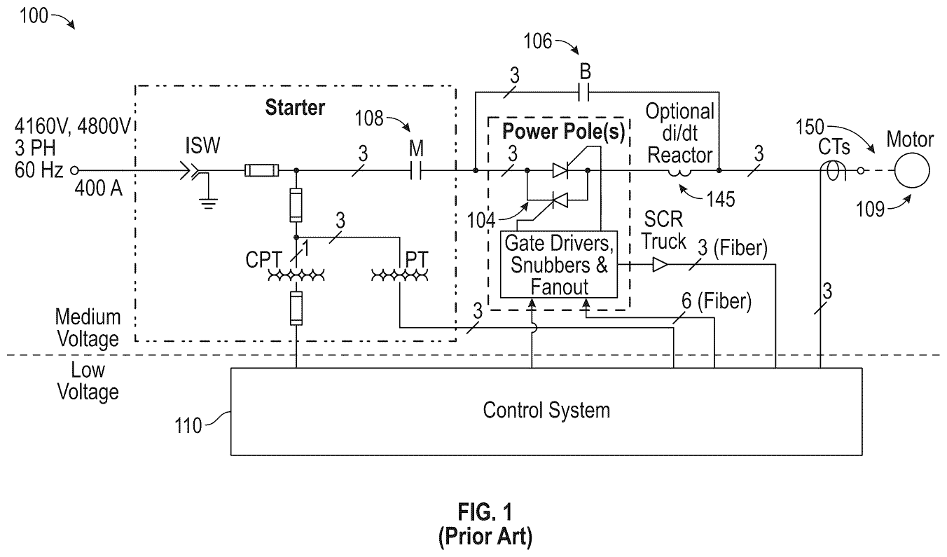

FIG. 1 illustrates a prior art circuit 100 for a medium voltage motor control center utilizing a reduced-voltage soft starter (RVSS). The circuit 100 can include a power source at 4160V or 4800V, 3-phase, 60 Hz, delivering 400A. The power can be supplied to the starter through an isolator switch (ISW). The starter section can include a control power transformer (CPT) and potential transformer (PT), which can provide control signals to the RVSS.

FIG. 1 also illustrates a long shielded cable 150 connected between a silicon-controlled rectifier (SRC) assembly 104 and the motor load 109. Long shielded cables used in medium voltage applications can introduce significant parasitic capacitance into the circuit 100. This parasitic capacitance can lead to high rates of current change (di/dt), which can cause severe electrical stress on the SCRs and potentially lead to their failure.

A di/dt smoothing inductor 145 can be positioned in series with the SCR assembly 104. This inductor 145 can be used as a historical mitigation option for long shielded cable applications to address high rates of current change. The inductor 145 can help to smooth out rapid changes in current (di/dt) that could potentially damage the SCRs of the SCR assembly 104 and other components in the circuit 100. This approach can be particularly relevant when dealing with long cables, which can introduce significant parasitic capacitance into the circuit 100.

The RVSS can include a silicon-controlled rectifier (SCR) assembly, identified as SCR Truck, which can incorporate gate drivers, snubbers, and a fanout network to manage the power flow to the motor load 109. The SCR assembly 104 can be used for controlling the voltage and current supplied to the motor load 109 during startup and stopping phases.

Traditionally, the circuit 100 can operate as follows: initially, the motor load 109 can be ramped up using the RVSS, which can gradually increase the voltage to the motor load 109 to reduce mechanical and electrical stress. During this ramping period, the bypass contact (B) 106 is open where current flows through the soft starter to the motor load 109. Once the motor load 109 reaches its operational speed, the bypass contact (B) can be closed to operate the motor load 109 with the RVSS and optional smoothing inductor bypassed. This operation applies full-voltage to the motor and the RVSS is out of the circuit. This process involves initially closing the B contact 106 to bypass both the reactor and RVSS, then opening the B contact 106 to put these items back into the circuit when stopping the motor with a RVSS ramp deceleration. This configuration can not only protect the SCRs but also permit the use of line-side power factor correction during motor startup. The inductor can help to smooth the current flow and mitigate the rapid changes in current caused by the parasitic capacitance of the long cables.

### Power Conditioning Unit

Some inventive concepts disclosed herein address the challenges associated with RVSS used in medium voltage motor control centers, specifically focusing on mitigating the adverse effects of long shielded cables and parasitic capacitance. Unlike traditional configurations, such as that shown in FIG. 1, that rely on di/dt smoothing inductors positioned in series with the silicon-controlled rectifiers (SCRs), some aspects of this disclosure introduce a power conditioning unit configured to improve system performance during ramp start and stop.

Some aspects of the present inventive concepts can simplify and enhance this traditional approach by introducing a power conditioning unit that, in some cases, remains continuously connected in the circuit. This power conditioning unit can integrate components such as a power factor correction capacitor (PFCC), a smoothing inductor, and a series fuse. The PFCC can supply reactive power compensation, reducing voltage sag at the point of common coupling (PCC) during high-slip start/stop events. In some cases, by maintaining these components in the circuit at all times, the requirement for a separate contactor 224 can be eliminated, thereby simplifying the system design.

In some cases, some aspects of the present inventive concepts may not necessitate the traditional smoothing inductor 150 positioned beside the SCRs. Instead, the power conditioning unit can effectively manage the parasitic capacitance and high di/dt issues introduced by long cables, providing consistent current smoothing and avoiding the electrical stress on the SCRs caused by high rates of current change. This continuous connection can also ensure adequate reactive power compensation, improving voltage stability and power quality during motor startup and operation.

The disclosed inventive concepts can provide a robust solution to the problems posed by long shielded cables in medium voltage applications, offering improved protection for SCRs, enhanced power quality, and greater operational flexibility compared to traditional approaches. The disclosed inventive concepts can reduce operational complexity and enhance the overall reliability and performance of the system. Furthermore, integrating these components into a single arrangement can also lead to reductions in both space and cost. By combining functions and reducing the need for separate components, the setup can be made more compact, which is particularly beneficial in environments where space is at a premium.

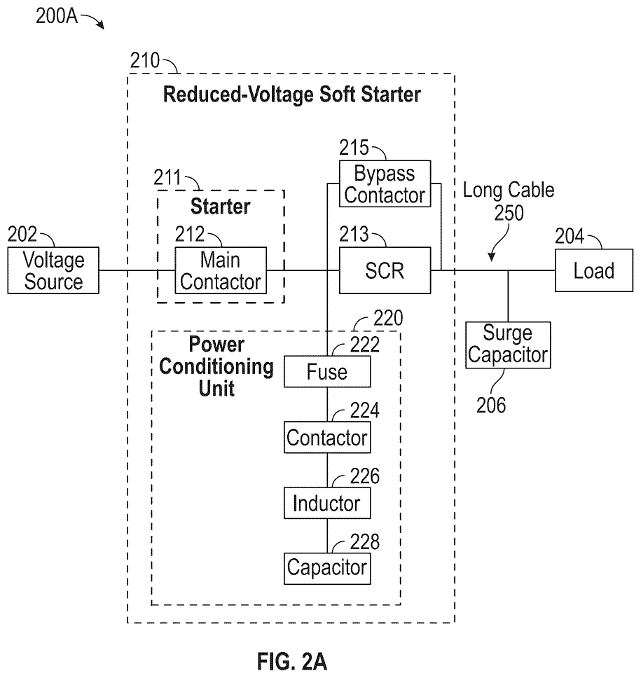

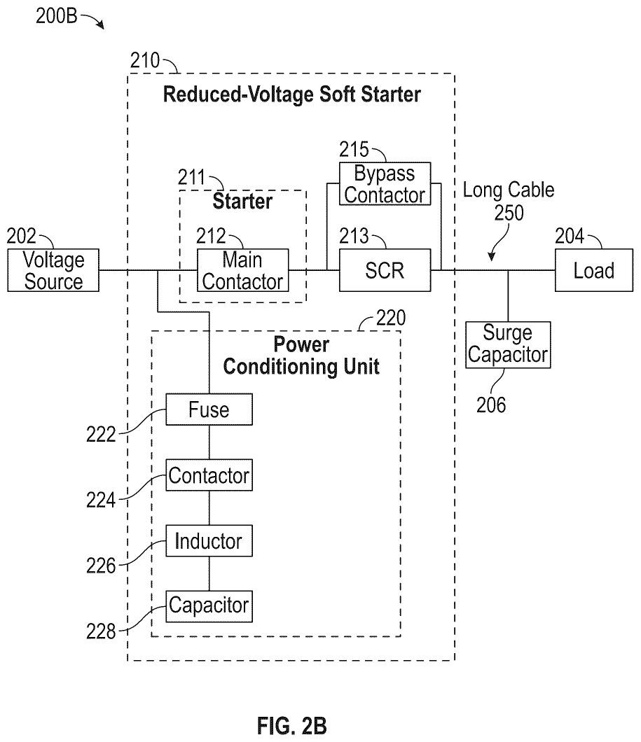

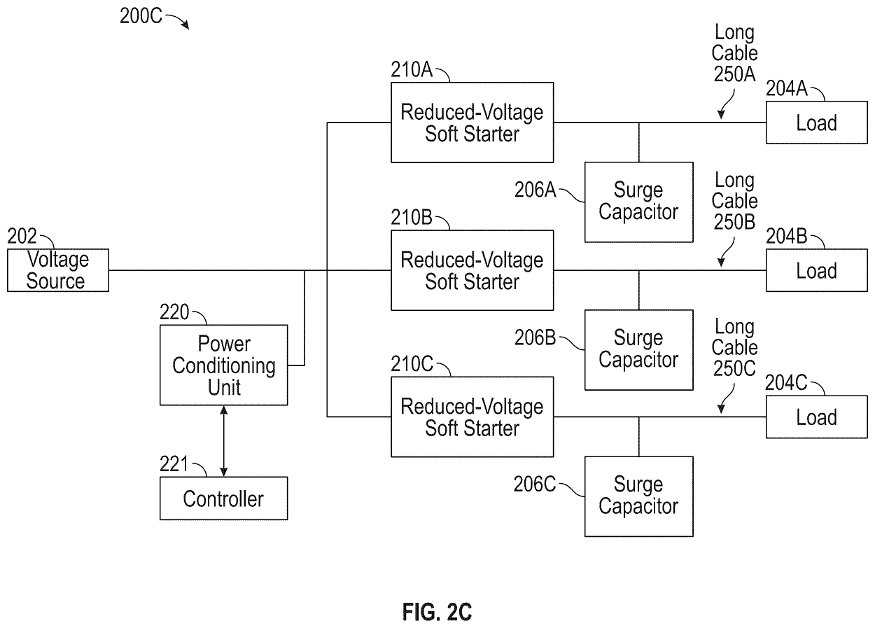

FIGS. 2A and 2B illustrate block diagrams of example systems 200A and 200B. FIG. 2A shows the power conditioning unit 220 positioned on a load side of the main contactor 212 in a single RVSS arrangement. FIG. 2B shows the power conditioning unit 220 positioned on a line side of the main contactor 212 in a multi-starter arrangement. The system 200A, 200B can include a voltage source 202, a load 204, a surge capacitor 206, and a reduced-voltage soft starter (RVSS) 210 electrically coupled to the voltage source 202 and the load 204. The RVSS 210 can include a starter 211, a set of silicon-controlled rectifiers (SCRs) 213, an inductor 226, a capacitor 228, and the power conditioning unit 220. It will be appreciated that the system 200A, 200B, the RVSS 210, and/or the power conditioning unit 220 can include fewer, more, or additional components, varying across embodiments.

Although only one RVSS is illustrated FIGS. 2A and 2B, in some cases, multiple RVSS units as shown in FIG. 2C can be treated with a collective power conditioning unit within a motor control center

Although only one RVSS is illustrated FIGS. 2A-2C, in some cases, multiple RVSS units can be configured in a single lineup within a motor control center. In some such cases, such a configuration can allow each RVSS unit to be connected to its own load, enabling the concurrent control and protection of multiple loads (e.g., motors) within the same system. These RVSS units can share common power sources, control circuitry, and/or cooling systems, and can be housed within a single cabinet or a series of interconnected cabinets. In some cases, each RVSS unit can operate independently but can be managed within the same centralized control framework, facilitating coordinated operation. Such a setup can enable efficient use of space and resources, with all units integrated into a cohesive lineup for streamlined installation, operation, and maintenance.

The voltage source 202 can supply power to the RVSS 210. In some cases, the voltage source 202 can be a medium voltage power source. For example, the voltage source 202 can supply 4160V or 4800V. In some cases, the voltage source 202 can be a low voltage power source. For example, the voltage source 202 can supply 240V or 480V. In some cases, the voltage source 202 can be a high voltage power source. For example, the voltage source 202 can supply 6.9 kV or higher. The voltage source 202 can be electrically coupled in series with the RVSS 210, such as with the starter 211 and/or the main contactor 212.

The load 204 can vary across embodiments. In some cases, the load 204 can include a motor, such as an induction motor, which can be used in various industrial applications. For example, the load 204 can include pumps, fans, compressors, or conveyors, each requiring controlled start/stop operations to reduce mechanical stress and electrical disturbances.

Historically, surge capacitors have been utilized at the load to protect motor end windings from fast-rising wave fronts such as lightning. In RVSS systems, particularly medium voltage applications, these capacitors are often removed during installation to avoid di/dt issues associated with long cables and accumulated parasitics. However, incorporating a smoothing inductor in the disclosed systems can allow for the use of surge capacitors, typically valued at 0.25 uF, 0.5 uF, or 0.75 uF in medium voltage applications.

The starter 211 can include various components such as an isolator switch, a control power transformer, a potential transformer, or the main contactor 212. The main contactor 212 can regulate the application of power to the system 200A, 200B. For example, the main contactor 212 can be configured to connect or disconnect the RVSS 210 from the voltage source 202. In some cases, closing the main contactor 212 with bypass contactor 215 closed can allow current flow through the system 200A, 200B, thereby initiating a startup sequence of the load 204.

The starter 211 and/or the main contactor 212 can be electrically coupled to power poles and the SCRs 213. The SCRs 213 can include, but are not limited to, gate drivers, snubbers, or a fanout network that can manage power flow to the load 204. The SCRs 213, in conjunction with the main contactor 212, can ensure controlled power delivery to the load 204, enabling smooth start and stop operations. For example, the gate drivers can be configured to control the firing angles of the SCRs 213, adjusting the voltage and current applied to the load 204.

The power conditioning unit 220 can be configured to manage the operation of the power factor correction capacitor (PFCC) 228, with or without the power conditioning contactor 224. The power conditioning unit 220 can include, but is not limited to, a capacitor fuse 222, a vacuum contactor 224, a smoothing inductor 226, and/or a power factor correction capacitor (PFCC) 228. These components can be positioned in series, in any order.

The capacitor fuse 222 can vary across embodiments. For example, the capacitor fuse 222 can include, but is not limited to, a fast-acting fuse designed to protect the PFCC 228 from overcurrent conditions. This protection can prevent damage to the PFCC 228 during fault conditions or excessive current flow events.

The optional vacuum contactor 224 can vary across embodiments. For example, the vacuum contactor 224 can include, but is not limited to, a contactor designed to selectively disconnect the PFCC 228 from the system 100, providing additional control over the power conditioning process.

The smoothing inductor 226 can vary across embodiments. For example, the smoothing inductor 226 can include, but is not limited to, an air-core inductor or an iron-core inductor. The inductor 226 can smooth the current, thereby mitigating high rates of current change that could potentially damage the SCRs 213. For instance, the inductor 226 can be selected based on the inductance value required to limit the current surge to acceptable levels.

The PFCC 228 can vary across embodiments. For example, the PFCC 228 can include, but is not limited to, a, two, three or four-terminal device designed to provide reactive power compensation. The PFCC 228 can assist during ramp start/stop operations by supplying leading VARs, which can effectively reduce voltage sag at the point of common coupling (PCC). This can improve the power quality during starting conditions. The PFCC 228 can be activated independently of the main contactor 212 or the bypass contactor 215. In this configuration, the PFCC 228 can operate either in synchronization with or independently from the main contactor 212 and/or the bypass contactor 215.

In some cases, the system 200A, 200B includes a bypass contactor 215 electrically connected in parallel with the series combination of the SCR 213. This configuration provides additional switching capabilities and improves the overall performance of the system. By connecting the bypass contactor 215 in parallel, the circuit can effectively manage high-frequency oscillations and provide a smoother current profile, thereby protecting the SCR 213 from potential damage caused by rapid changes in current.

The power conditioning unit 220 can be connected to the system 100 in different configurations based on the application requirements. In some cases, the power conditioning unit 220 is placed on a load side of the main contactor 212, as shown in FIG. 2A. This configuration can be beneficial for providing direct compensation to a single load. In other cases, the power conditioning unit 220 is placed on a line side of the main contactor 212, as shown in FIG. 2B, offering broader system-level power quality improvements. The placement can be optimized based on factors such as the length of the cable 250, the nature of the load 204, and the specific operational goals of the power conditioning system.

In some cases, for example as shown in FIG. 2C, the system 200C can include a controller 221 configured to manage the operation of the power conditioning unit 220. In some configurations, multiple RVSS 210 systems can share a single external power factor correction (PFC) power conditioning unit, which can be controlled by the controller 221. The controller 221 can coordinate the operation of the PFC capacitors, smoothing inductor, and contactors within the power conditioning unit 220.

The long cable 250 can be used to connect the RVSS 210 to the load 204. The length of the cable 250 can introduce significant parasitic capacitance (e.g., 0.1 uF, 0.2 uF, 0.3 uF, 0.4 uF, 0.5 uF, or more), which can impact the durability and performance of the system 200A, 200B. This parasitic capacitance can result in high rates of current change that can lead to di/dt current and potential failures of the SCRs 213. The length of the cable 250 can vary depending on the specific application and installation requirements. For example, in some cases, a cable may be considered a long cable if it is greater than 150 meters, 200 meters, 250 meters, 300 meters, 350 meters, or longer (+/−25 meters). In some cases, a cable may be considered a long cable if a total length of the long shielded cable exceeds Y meters, where Y is one of 150 meters, 180 meters, 210 meters, 240 meters, 270 meters, or 300 meters (+/−10 meters).

Conventionally, load-side cable capacitance from shielded cables may be treated with a series inductor when the capacitance exceeds 0.3 uF. This threshold can be surpassed with cable lengths greater than 800 feet, whether by a single run or parallel runs of shielded cable per phase. Additionally, a contributing factor to high di/dt currents is the combination of line-side power conditioning PFC capacitors and long load-side cables. By addressing these factors with a smoothing inductor, the proposed system can effectively mitigate high di/dt currents and enhance the performance and reliability of the RVSS.

The parasitic capacitance introduced by the long cable 250 can cause issues such as high di/dt, which can result in severe electrical stresses on the SCRs 213 and other components. This can lead to an inoperable state or the need to bypass the RVSS to allow full-voltage starting the load. The power conditioning unit 220, including components such as the PFCC 228 and the smoothing inductor 226, can be configured to mitigate these effects by providing reactive power compensation and smoothing the current. By reducing the impact of the parasitic capacitance, the power conditioning unit 220 can enhance the overall stability and reliability of the system 200A, 200B, improving performance even in the presence of long cables. In some instances, the smoothing inductor applied to the power conditioning unit 220 can allow for a certain range of surge capacitance to be installed at the load without concern for di/dt damage to the RVSS SCRs.

FIG. 2C illustrates a block diagram of a system 200C that includes multiple reduced-voltage soft starters (RVSS) 210A, 210B, and 210C, each connected to separate loads 204A, 204B, and 204C (individually or collectively referred to as load 204) through long cables 250A, 250B, and 250C (individually or collectively referred to as cable 250). A surge capacitor 206A, 206B, 206C (individually or collectively referred to as surge capacitor 206) is connected in shunt. The system includes a voltage source 202 supplying power to a power conditioning unit 220, which is managed by a controller 221. The power conditioning unit 220 is configured to provide power factor correction and current smoothing for the RVSS units 210A, 210B, and 210C. The controller 221 coordinates the operation of the power conditioning unit 220. This configuration can allow for the concurrent control and protection of multiple motor loads, with the RVSS units sharing common power sources and control circuitry within a centralized system. The integration of the power conditioning unit 220 enhances the overall durability of the RVSS units, mitigating issues such as high di/dt currents and parasitic capacitance effects introduced by the long cables 250A, 250B, and 250C.

Although FIG. 2C illustrates a configuration with three reduced-voltage soft starters (RVSS) 210A, 210B, and 210C, it will be appreciated that the system is not limited to this specific number. Fewer or more RVSS units may be used depending on the application requirements and system design. The power conditioning unit 220 and controller 221 can be adapted to manage varying numbers of RVSS units, providing flexibility in scaling the system to meet different operational needs. Furthermore, it will be appreciated that the RVSSs 210A, 210B, and 210C may be an embodiment of the RVSS 210 of FIGS. 2A and/or 2B.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, 0.1 degree, or otherwise.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A system for regulating power delivery to a load, the system comprising:
a reduced-voltage soft starter (RVSS) comprising a plurality of silicon-controlled rectifiers (SCRs), the SCRs positioned to regulate voltage applied to the load;
a contactor electrically coupled between a power source and the RVSS, the contactor configured to selectively establish or interrupt electrical continuity between the power source and the RVSS; and
a power conditioning circuit electrically coupled between the power source and the load in parallel with the RVSS, the power conditioning circuit comprising a power factor correction capacitor, and a smoothing inductor electrically connected in series with the power factor correction capacitor,
wherein the smoothing inductor and the power factor correction capacitor define a conductive path positioned to carry current between the power source and the load independently of the RVSS, and
wherein the conductive path is arranged to attenuate current transients resulting from interaction between the power factor correction capacitor and a parasitic capacitance of a shielded cable electrically coupling the RVSS to the load.

2. The system of claim 1, wherein the smoothing inductor is electrically positioned between the power factor correction capacitor and a junction with the shielded cable, and is dimensioned to oppose a rate of current change associated with interaction between the power factor correction capacitor and the parasitic capacitance of the shielded cable.

3. The system of claim 1, wherein the power conditioning circuit is electrically coupled in a shunt path that bypasses the RVSS and provides a continuous conductive route between the power source and the load.

4. The system of claim 3, wherein the conductive route formed by the power conditioning circuit remains closed during both energization and de-energization of the RVSS.

5. The system of claim 1, wherein the power factor correction capacitor and the smoothing inductor are arranged to form an LC network with the shielded cable capacitance, such that peak transient currents are diverted from the SCRs.

6. The system of claim 1, further comprising a shielded cable electrically coupled between the RVSS and the load, the shielded cable having the parasitic capacitance.

7. The system of claim 6, wherein the parasitic capacitance of the shielded cable is at least 0.3 microfarads.

8. The system of claim 6, wherein the shielded cable has a length greater than 800 feet.

9. The system of claim 1, wherein the smoothing inductor comprises a magnetic core selected from the group consisting of iron-core, ferrite-core, laminated steel-core, powder iron-core, or nanocrystalline-core.

10. The system of claim 1, wherein the power conditioning circuit further comprises a fuse electrically connected in series with the power factor correction capacitor and the smoothing inductor.

11. The system of claim 1, wherein the power factor correction capacitor is electrically positioned on a side of the contactor that is electrically proximate to the power source.

12. The system of claim 1, wherein the power factor correction capacitor is electrically positioned on a side of the contactor that is electrically proximate to the load.

13. The system of claim 1, wherein the power conditioning circuit is electrically connected without a contactor or switch for disconnecting the power factor correction capacitor.

14. The system of claim 1, wherein the RVSS omits a bypass contactor connected in parallel with the SCRs.

15. The system of claim 1, wherein the smoothing inductor is electrically connected between a terminal of the power factor correction capacitor and a conductive node shared with the shielded cable, the power factor correction capacitor and the smoothing inductor being electrically connected in series with a fuse to form a continuous, unbroken conduction path from the power source to the load, the conduction path bypassing the SCRs,
wherein the smoothing inductor has an inductance value selected such that peak di/dt resulting from a transient charging or discharging event between the power factor correction capacitor and a parasitic capacitance of the shielded cable remains below a rate of current change capable of triggering or damaging the SCRs.

16. The system of claim 1, wherein the conductive path defined by the smoothing inductor and the power factor correction capacitor is electrically connected during a startup sequence of the reduced-voltage soft starter, and wherein the conductive path limits a peak current surge associated with energization of the parasitic capacitance of the shielded cable.

17. A method of regulating power delivery to a load, the method comprising:
energizing a reduced-voltage soft starter (RVSS) from a power source, the RVSS comprising a plurality of silicon-controlled rectifiers (SCRs) electrically coupled to a contactor;
closing the contactor to apply voltage from the power source through the RVSS to the load via a shielded cable;
operating the SCRs to regulate voltage to the load during a startup or shutdown sequence;
conducting current from the power source to the load through a power conditioning circuit electrically connected in parallel with the RVSS, the power conditioning circuit comprising a power factor correction capacitor and a smoothing inductor connected in series; and
passing current through the smoothing inductor in the power conditioning circuit to attenuate transient current caused by interaction between the power factor correction capacitor and a parasitic capacitance of the shielded cable,
wherein the current conducted through the power conditioning circuit bypasses the SCRs of the RVSS.

18. The method of claim 17, wherein conducting current through the power conditioning circuit comprises establishing an uninterrupted electrical conduction path from the power source to the load through the smoothing inductor and the power factor correction capacitor, the conduction path bypassing the contactor and the SCRs of the reduced-voltage soft starter throughout a startup sequence.

19. The method of claim 18, wherein the current conducted through the power conditioning circuit includes a reactive charging current arising from interaction between the power factor correction capacitor and a parasitic capacitance of the shielded cable, and wherein the reactive charging current is directed through the smoothing inductor and excluded from the conduction path of the SCRs.

20. The method of claim 19, wherein passing current through the smoothing inductor includes limiting a rate of change of current associated with an initial energization of the parasitic capacitance of the shielded cable to a value less than a predetermined maximum di/dt threshold of the silicon-controlled rectifiers.
